(19) United States
(12) Patent Application Publication
(10) Pub. No.: US 2020/0205242 A1
(43) Pub. Date: Jun. 25, 2020

(54) MICROWAVE HEATING DEVICE

(71) Applicant: METAL INDUSTRIES RESEARCH & DEVELOPMENT CENTRE, KAOHSIUNG (TW)

(72) Inventors: Yi-San CHANG, TAINAN CITY (TW); Yii-Der WU, KAOHSIUNG CITY (TW); I-Chun CHUNG, KAOHSIUNG CITY (TW)

(21) Appl. No.: 16/224,827

(22) Filed: Dec. 19, 2018

(51) Int. Cl. H05B 6/64; H05B 6/66; H05B 6/68; H05B 6/70; H05B 6/72

(52) U.S. Cl. CPC H05B 6/6402; H05B 6/662; H05B 6/681; H01L 21/67115; H05B 6/72; H05B 6/6408; H05B 6/6447; H05B 6/707

(57) ABSTRACT

A microwave heating device includes a waveguide, a metal plate, a magnetron, a heat generating plate, a thermal insulation member and an adjusting member. The waveguide has a waveguide space, in which a sidewall of the waveguide has an opening communicating the waveguide space. The metal plate covers the opening to seal the waveguide space. The magnetron is configured to generate microwaves, in which an output end of the magnetron protrudes into the waveguide space. The heat generating plate is disposed in the waveguide space and is contacted with the metal plate, in which the heat generating plate is configured to absorb microwaves. The thermal insulation member is partially covers the heat generating plate. The adjusting member is disposed in the waveguide space and is located under the heat generating plate.

### BACKGROUND

### Field of Invention

The present invention relates to a microwave heating device. More particularly, the present invention relates to a microwave heating device which is applicable to a vacuum processing apparatus for processing semiconductors.

### Description of Related Art

Electric resistance heating devices are generally used in semiconductor manufacturing processes. Since a heating coil is covered in a heating body of the electric resistance heating device, the electric resistance heating device itself is difficult to manufacture, and is limited by the manufacturing method, thus causing defects and affecting the service life of the electric resistance heating device. In addition, the electric resistance heating device has a smaller heating rate and has a serious energy consumption problem, which does not meet the requirement of use efficiency.

### SUMMARY

Therefore, one objective of the present invention is to provide a microwave heating device which has advantages of simple structure, easy operation and energy saving.

According to the aforementioned objectives, the present invention provides a microwave heating device. The microwave heating device includes a waveguide, a metal plate, a magnetron, a heat generating plate, a thermal insulation member and an adjusting member. The waveguide has a waveguide space, in which a sidewall of the waveguide has an opening communicating the waveguide space. The metal plate covers the opening to seal the waveguide space. The magnetron is configured to generate microwaves, in which an output end of the magnetron protrudes into the waveguide space. The heat generating plate is disposed in the waveguide space and is contacted with the metal plate, in which the heat generating plate is configured to absorb microwaves. The thermal insulation member is partially covers the heat generating plate. The adjusting member is disposed in the waveguide space and is located under the heat generating plate.

According to an embodiment of the present invention, the microwave heating device further includes a microwave isolator. The magnetron and the microwave isolator are respectively located at two opposite sides of the adjusting member.

According to an embodiment of the present invention, the waveguide is a WR340 waveguide, and a microwave frequency of the magnetron is 2.45 GHz.

According to an embodiment of the present invention, the waveguide is a WR430 waveguide, and a microwave frequency of the magnetron is 915 MHz.

According to an embodiment of the present invention, the metal plate includes an aluminum plate, an iron plate or a stainless steel plate.

According to an embodiment of the present invention, the heat generating plate includes a silicon carbide plate.

According to an embodiment of the present invention, the thermal insulation member includes a plastic thermal insulation member or a ceramic thermal insulation member.

According to an embodiment of the present invention, the adjusting member includes a trapezoidal structure, and the trapezoidal structure has a top surface and at least two inclined surfaces connected to the top surface, and the top surface is located under the heat generating plate.

According to an embodiment of the present invention, the metal plate has an inner surface and an outer surface opposite to the inner surface, in which the inner surface faces towards the waveguide space and is contacted with the heat generating plate, and the outer surface faces towards an outer side of the waveguide. The microwave heating device further includes a vacuum chamber covering the outer surface of the metal plate.

According to an embodiment of the present invention, the microwave heating device further includes a temperature sensor. The temperature sensor is disposed in the vacuum chamber.

According to the aforementioned embodiments of the present invention, the microwave heating device has the adjusting member, and the microwave heating temperature can be adjusted by changing different heights of adjusting members, or by adjusting the height of the adjusting member under the same condition of the magnetron power. Therefore, the microwave heating device of the present invention has advantages of easy operation and energy saving.

On the other hand, the temperature distribution effect and the heating rate of the microwave heating device of the present invention are better than those of the conventional electric resistance heating device, and the overall structure of the microwave heating device of the present invention is also simpler than that of the electric resistance heating device, and the energy consumption of the microwave heating device of the present invention is also low. In addition, the microwave heating device is easy to control in the single mode and is suitable to be used in a vacuum environment.

### BRIEF DESCRIPTION OF THE DRAWINGS

The invention can be more fully understood by reading the following detailed description of the embodiment, with reference made to the accompanying drawings as follows:

FIG. 1 is a schematic structural diagram showing a microwave heating device in accordance with an embodiment of the present invention;

FIG. 2 is a partial cross-sectional view showing the microwave heating device in accordance with an embodiment of the present invention; and

FIG. 3A to FIG. 3C are schematic diagrams respectively showing a microwave heating device without using any adjusting member, a microwave heating device using an adjusting member having a first height, and a microwave heating device using an adjusting member having a second height.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

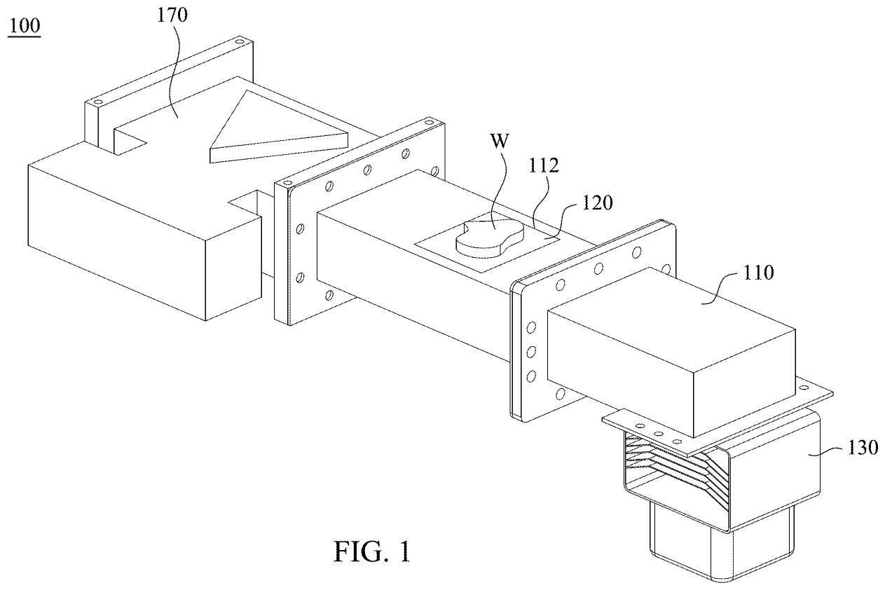

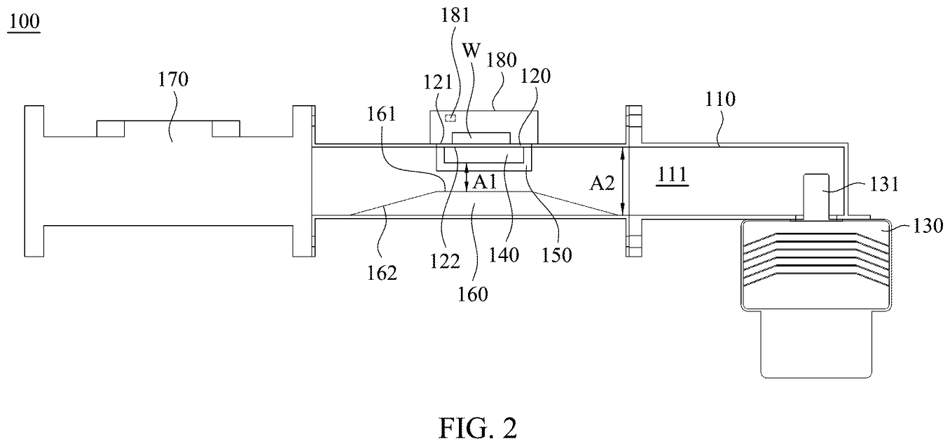

Simultaneously referring to FIG. 1 and FIG. 2, FIG. 1 and FIG. 2 are respectively a schematic structural diagram and a partial cross-sectional view showing a microwave heating device 100 in accordance with an embodiment of the present invention. The microwave heating device 100 mainly includes a waveguide 110, a metal plate 120, a magnetron 130, a heat generating plate 140, a thermal insulation member 150, an adjusting member 160, a microwave isolator 170 and a vacuum chamber 180.

Referring to FIG. 1 and FIG. 2 again, in the present embodiment, the waveguide 110 is a rectangular pipe and has a waveguide space 111. A sidewall of the waveguide 110 has an opening 112 communicated with the waveguide space 111. The metal plate 120 covers the opening 112 so as to seal the waveguide space 111. In the present embodiment, the metal plate 120 is embedded at the opening 112 and is mainly used to conduct heat to provide uniform heat source for an object W to be heated. The metal plate 120 has a top surface 121 and a bottom surface 122, and the top surface 121 is a surface which faces towards an outer side of the waveguide 110, and the bottom surface 122 is a surface which faces towards the waveguide space 111, in which the top surface 121 is defined as a surface which is contacted with the object W to be heated. In some examples, the metal plate 120 may be an aluminum plate, an iron plate or a stainless steel plate. In the present embodiment, the vacuum chamber 180 covers the top surface 121 of the metal plate 120, and there is a vacuum environment inside of the vacuum chamber 180. The object W to be heated is located in the vacuum environment and is disposed on the metal plate 120. In some embodiments, there is also a vacuum environment inside of the waveguide space 111.

As shown in FIG. 1 and FIG. 2, the magnetron 130 is disposed on one end of the waveguide 110, and the magnetron 130 is configured to generate microwaves. An output end 131 of the magnetron 130 protrudes inside of the waveguide space 111. The heat generating plate 140 is disposed in the waveguide space 111 and is contacted with the bottom surface 122 of the metal plate 120. The heat generating plate 140 is made of microwave absorbing material, such as silicon carbide. The heat generating plate 140 is configured to absorb microwaves. Therefore, microwaves generated by the magnetron 130 which is disposed on one end of the waveguide 110 is output from the output end 131 and is transmitted to the other end of the waveguide 110. Meanwhile, when the magnetron 130 generates microwaves, the heat generating plate 140 can be heated by absorbing microwaves so as to transmit heat to the metal plate 120 uniformly for heating the object W located on the metal plate 120.

In one embodiment, the waveguide 110 is WR340 waveguide, and the frequency of the magnetron 130 is 2.45 GHz. In other embodiments, the waveguide 110 is WR430 waveguide, and the frequency of the magnetron 130 is 915 MHz. Therefore, microwaves can be formed in TE₁₀ single mode in the waveguide 110. The microwave heating device 100 of the present embodiment is mainly used to heat micro semiconductors with smaller than 1 inch diameter, such as 0.5 inch diameter. In other words, the overall size of the microwave heating device 100 of the present invention is smaller than that of a conventional microwave heating device, and therefore it is merely necessary to use single mode microwave which has an advantage of easy-to-control.

Referring to FIG. 1 and FIG. 2 again, the thermal insulation member 150 is located in the waveguide space 111, and the thermal insulation member 150 partially covers a portion of the heat generating plate 140 which is not contacted with the metal plate 120. In one present embodiment, the thermal insulation member 150 may be a plastic thermal insulation member or a ceramic thermal insulation member. The thermal insulation member 150 can be passed by the microwaves without being affected by the microwaves, so as to ensure that heat energy generated by the heat generating plate 140 can be completely transmitted to the metal plate 120. Therefore, the thermal insulation member 150 has a function of restricting heat transmission direction.

Referring to FIG. 1 and FIG. 2, the adjusting member 160 is disposed in the waveguide space 111 and is located below the heat generating plate 140. The adjusting member 160 is mainly used to shrink a width of the waveguide space 111 so as to increase the microwave energy density. In the present embodiment, the adjusting member 160 is a trapezoidal structure which has a top surface 161 and at least two inclined surfaces 162 connected to the top surface 161. The top surface 161 of the adjusting member 160 is located directly below the heat generating plate 140, that is, a highest portion of the adjusting member 160 is located directly below the heat generating plate 140, so that a distance A1 between the top surface 161 and the heat generating plate 140 is smaller than a width A2 of the waveguide space 111. Therefore, when microwaves generated by the magnetron 130 is transmitted from the inclined surface 162 of the adjusting member 160 to the top surface 161 of the adjusting member 160, microwaves will be compressed because the space is shrunken, thereby concentrating the microwave energy on the heat generating plate 140 to increase temperature of the object W. In one embodiment, the adjusting member 160 is made of metal reflecting material, such as aluminum, copper, or stainless steel.

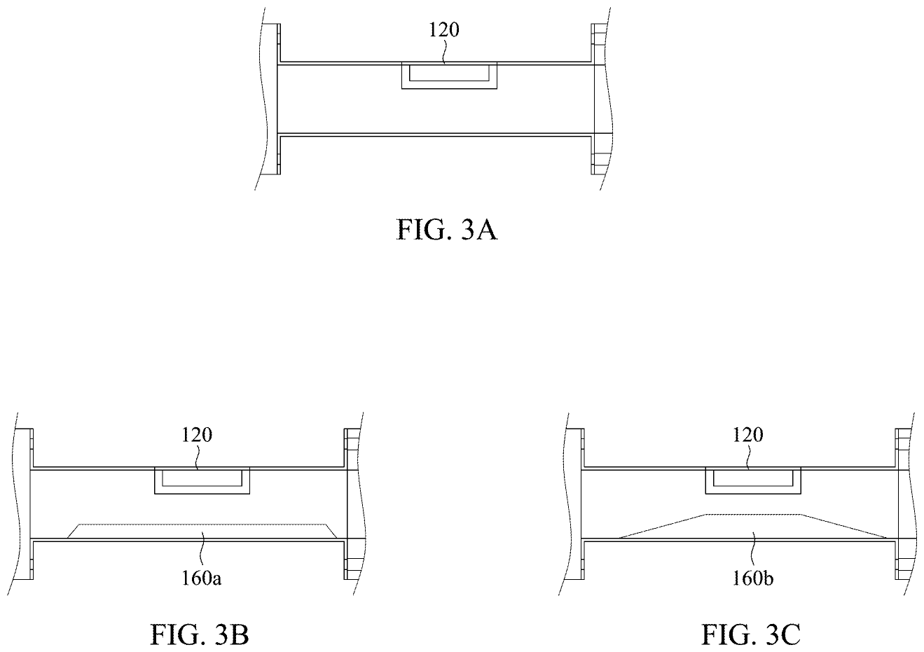

Referring to FIG. 3A to FIG. 3C, FIG. 3A to FIG. 3C are schematic diagrams respectively showing a microwave heating device without using any adjusting member, a microwave heating device using an adjusting member having a first height, and a microwave heating device using an adjusting member having a second height. Under the same condition of microwave power, if a microwave heating device does not use any adjusting member (as shown in FIG. 3A), the highest temperature of the metal plate 120 is 126.43° C., the lowest temperature of which is 119.47° C., and surface temperature distribution of which is 97.1%. When a microwave heating device uses a first adjusting member 160a (as shown in FIG. 3B), the highest temperature of the metal plate 120 is 154.72° C., the lowest temperature of which is 146.35° C. and surface temperature distribution of which is 97.2%. When a microwave heating device uses a second adjusting member 160b (as shown in FIG. 3C), the highest temperature of the metal plate 120 is 203.99° C. the lowest temperature of which is 189.10° C., and surface temperature distribution of which is 96.2%. Therefore, when a height of the adjusting member becomes greater, the distance between the top surface of the adjusting member and the metal plate becomes smaller, thereby compressing energy density. In other words, under the same microwave power condition, if microwave heating device 100 uses higher adjusting member, temperature of the metal plate 120 is more likely to be increased. Therefore, the temperature of the metal plate 120 can be adjusted by changing different heights of adjusting member.

Referring to FIG. 1 and FIG. 2 again, the microwave isolator 170 and the magnetron 130 are respectively disposed on two opposite ends of the waveguide 110. Therefore, microwave generated by the magnetron 130 is first transmitted along the waveguide 110 to the heat generating plate 140, and then is transmitted to the microwave isolator 170. The microwave isolator 170 is mainly used to absorb unnecessary microwaves so as to prevent the microwaves from being reflected by the microwave isolator 170 and to prevent the quality of microwaves from being affected.

In some embodiments, a temperature sensor 181 can be disposed in the vacuum chamber 180. The temperature sensor 181 can be used to detect actual temperature of the heat generated from the microwaves which can be used as a reference for a feedback controller. On the other hand, users also can adjust power of the magnetron 130 according to the detected temperature, or can control microwave temperature by changing the adjusting members with different heights.

According to the aforementioned embodiments of the present invention, the microwave heating device has the adjusting member, and the microwave heating temperature can be adjusted by changing different heights of adjusting members, or by adjusting the height of the adjusting member under the same condition of the magnetron power. Therefore, the microwave heating device of the present invention has advantages of easy operation and energy saving.

On the other hand, the temperature distribution effect and the heating rate of the microwave heating device of the present invention are better than those of the conventional electric resistance heating device, and the overall structure of the microwave heating device of the present invention is also simpler than that of the electric resistance heating device, and the energy consumption of the microwave heating device of the present invention is also low. In addition, the microwave heating device is easy to control in the single mode and is suitable to be used in a vacuum environment.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A microwave heating device, comprising:
a waveguide having a waveguide space, wherein a sidewall of the waveguide has an opening communicating the waveguide space;
a metal plate covering the opening to seal the waveguide space;
a magnetron configured to generate microwaves, wherein an output end of the magnetron protrudes into the waveguide space;
a heat generating plate disposed in the waveguide space and contacted with the metal plate, wherein the heat generating plate is configured to absorb the microwaves;
a thermal insulation member partially covering the heat generating plate; and
an adjusting member disposed in the waveguide space under the heat generating plate.

2. The microwave heating device of claim 1, further comprising a microwave isolator, wherein the magnetron and the microwave isolator are respectively located at two opposite sides of the adjusting member.

3. The microwave heating device of claim 1, wherein the waveguide is a WR340 waveguide, and a microwave frequency of the magnetron is 2.45 GHz.

4. The microwave heating device of claim 1, wherein the waveguide is a WR430 waveguide, and a microwave frequency of the magnetron is 915 MHz.

5. The microwave heating device of claim 1, wherein the metal plate comprises an aluminum plate, an iron plate or a stainless steel plate.

6. The microwave heating device of claim 1, wherein the heat generating plate comprises a silicon carbide plate.

7. The microwave heating device of claim 1, wherein the thermal insulation member comprises a plastic thermal insulation member or a ceramic thermal insulation member.

8. The microwave heating device of claim 1, wherein the adjusting member comprises a trapezoidal structure, and the trapezoidal structure has a top surface and at least two inclined surfaces connected to the top surface, and the top surface is located under the heat generating plate.

9. The microwave heating device of claim 1, wherein
the metal plate has an inner surface and an outer surface opposite to the inner surface, wherein the inner surface faces towards the waveguide space and is contacted with the heat generating plate, and the outer surface faces towards an outer side of the waveguide; and
the microwave heating device further comprises a vacuum chamber covering the outer surface of the metal plate.

10. The microwave heating device of claim 1, further comprising a temperature sensor disposed in the vacuum chamber.
